(19) United States
(12) Patent Application Publication
(10) Pub. No.: US 2022/0410605 A1
(43) Pub. Date: Dec. 29, 2022

(54) THREE-DIMENSIONAL PRINTED ANTENNA, METHOD FOR MANUFACTURING THE SAME, AND ELECTRONIC DEVICE

(71) Applicant: iCare Diagnostics International Co. Ltd., New Taipei City (TW)

(72) Inventors: KAI YANG, New Taipei (TW); CHIEN-YU GU, New Taipei (TW); YU-MIN WANG, New Taipei (TW)

(21) Appl. No.: 17/844,913

(22) Filed: Jun. 21, 2022

(30) Foreign Application Priority Data
Jun. 29, 2021 (CN) 202110726740.3

(51) Int. Cl. B41M 1/12; H01Q 1/38; B41M 1/22; B41M 1/30

(52) U.S. Cl. CPC B41M 1/12; H01Q 1/38; B41M 1/22; B41M 1/30

(57) ABSTRACT

A method for manufacturing a flex-tolerant three-dimensional printed antenna suitable for use in an electronic device provides a three-dimensional printed antenna with base layer, radiation layer, through holes, and feeder. The radiation layer includes a first radiation region, at least one second radiation region, and a feed end. A region between the first and second radiation regions is defined as a bent region. The radiation layer is formed by a screen-printing plate by a planar printing process. The through holes on the bent region form a line for bending. The feeder is electrically connected to the feed end. The second radiation region is canted from the bending line with respect to the first radiation region to form the three-dimensional printed antenna. The three-dimensional printed antenna and an electronic device are also disclosed.

### FIELD

The subject matter relates to antennas, and more particularly, to a three-dimensional printed antenna, a method for manufacturing the three-dimensional printed antenna, and an electronic device with the three-dimensional printed antenna.

### BACKGROUND

A radiation surface of an antenna can be manufactured by a manufacturing process applied to a flexible printed circuit (FPC) or a printed circuit board (PCB). Then, an end of a feeder is welded on a feed end of the radiation surface, and the other end of the feeder is connected to a communication module to transfer signals.

However, the existing manufacturing process of the circuit board is complex and costly, as it includes multiple steps such as metal etching, electroplating, and water washing. Furthermore, the circuit board manufactured by such process has a poor flexibility. When the circuit board is bent or warped, a circuit layer of the circuit board may be separated from a base layer. In addition, in order to increase the radiation performance of the antenna, the radiation surface will be relatively large, which will increase a volume of the antenna. Thus, there is room for improvement in the art.

### BRIEF DESCRIPTION OF THE DRAWINGS

Implementations of the present technology will now be described, by way of example only, with reference to the attached figures.

FIG. 1 is a flowchart of an embodiment of a method for manufacturing a three-dimensional printed antenna according to the present disclosure.

FIG. 2 is a diagrammatic view of an embodiment of a base layer according to the present disclosure.

FIG. 3 is a diagrammatic view of an embodiment of a screen-printing plate according to the present disclosure.

FIG. 4 is a cross-sectional view of the screen-printing plate of FIG. 3.

FIG. 5 is a diagrammatic view showing a metal radiation layer printed on the base layer of FIG. 2.

FIG. 6 is a cross-sectional view of a bending region of the metal radiation layer and the base layer of FIG. 5.

FIG. 7 is a diagrammatic view of an embodiment of a planar printed antenna after connecting a feeder to the metal radiation layer of FIG. 5.

FIG. 8 is a diagrammatic view of another embodiment of a planar printed antenna according to the present disclosure.

FIG. 9 is a diagrammatic view of another embodiment of a planar printed antenna according to the present disclosure.

FIG. 10 is a diagrammatic view of a three-dimensional printed antenna after bending the planar printed antenna of FIG. 7.

FIG. 11 is a diagrammatic view of an embodiment of an electronic device according to the present disclosure.

FIG. 12 is a diagram showing gain test results of the planar printed antenna of FIG. 7.

FIG. 13 is a photo showing gain test results of the planar printed antenna of FIG. 7.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

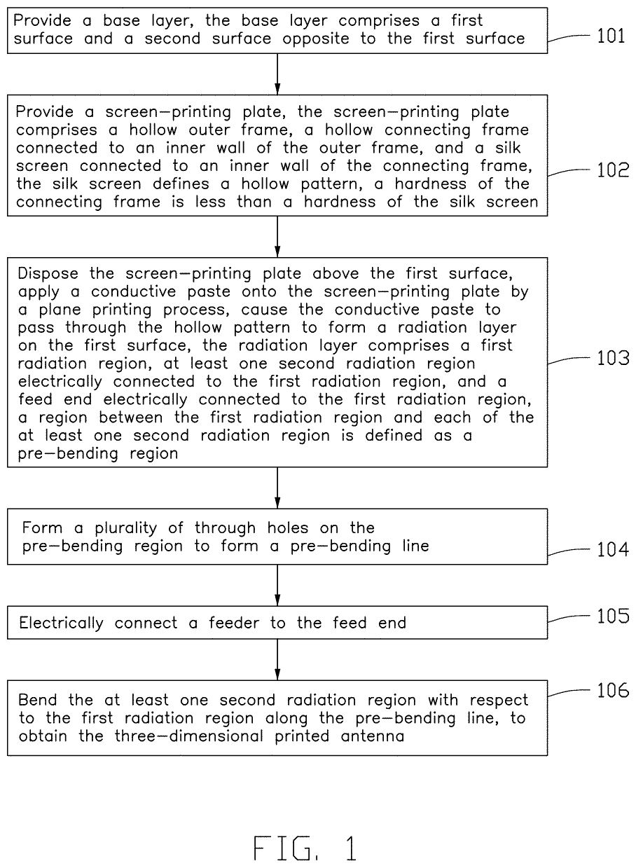

FIG. 1 illustrates a method for manufacturing a three-dimensional printed antenna 200 Referring to FIG. 1, the method is presented in accordance with an embodiment. The method is provided by way of example, as there are a variety of ways to carry out the method. The method can begin at block 101.

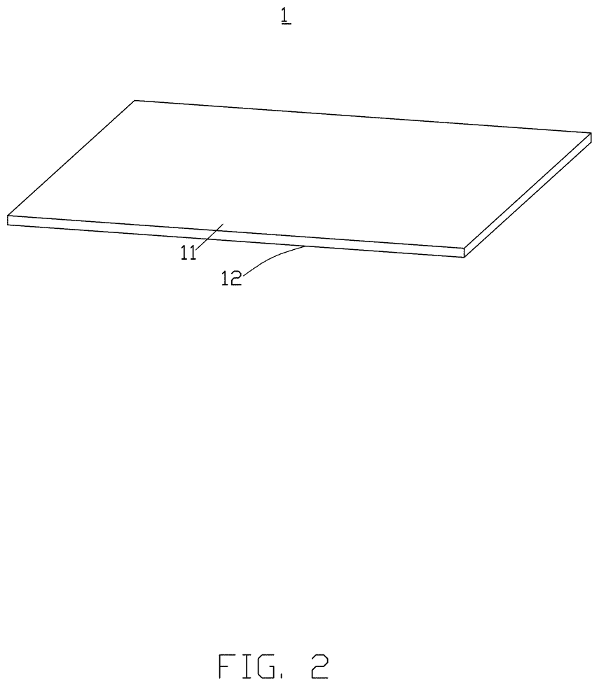

In block 101, referring to FIG. 2, a base layer 1 is provided. The base layer 1 includes a first surface 11 and a second surface 12 opposite to the first surface 11.

In an embodiment, the base layer 1 is made of an insulating resin, such as polyphenylene oxide (PPO), polyimide (PI), polyethylene terephthalate (PET), and polyethylene naphthalate (PEN).

In an embodiment, the base layer 1 is made of PI or PET which has excellent mechanical properties and flexibility, and a cost of the planar printed antenna 100 can be reduced.

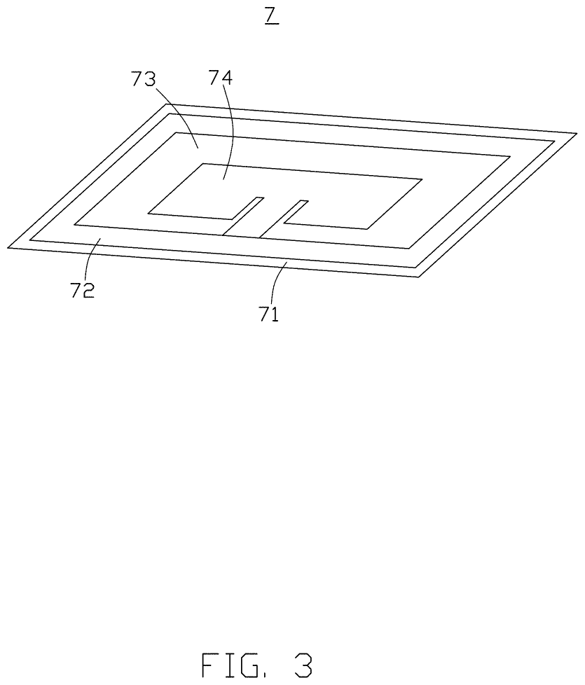

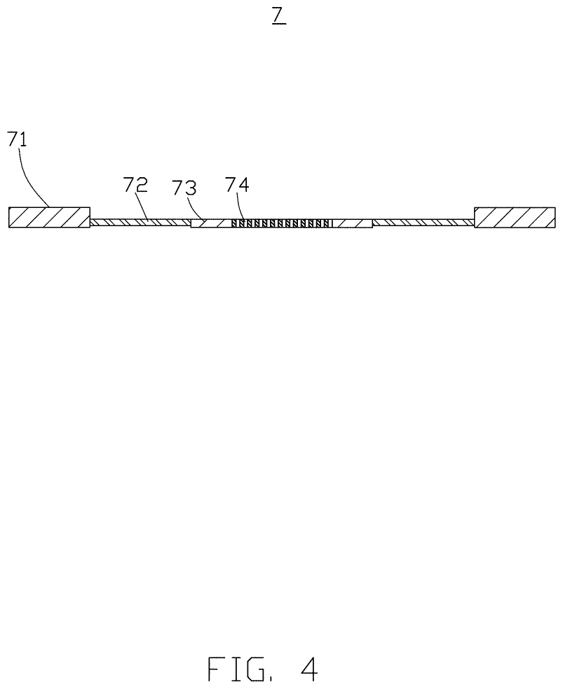

In block 102, referring to FIGS. 3 and 4, a screen-printing plate 7 is provided. The screen-printing plate 7 includes a hollow outer frame 71, a hollow connecting frame 72 connected to an inner wall of the outer frame 71, and a silk screen 73 connected to an inner wall of the connecting frame 72. The silk screen 73 has a hollow pattern 74. A hardness of the connecting frame 72 is less than a hardness of the silk screen 73.

In an embodiment, the screen-printing plate 7 has a composite structure made of different materials.

In an embodiment, the outer frame 71 may be made of, but is not limited to, aluminum alloy or wood.

In an embodiment, the connecting frame 72 may be made of, but is not limited to, polymer or metal.

In an embodiment, the silk screen 73 may be made of, but is not limited to, metal.

In an embodiment, the silk screen 73 may be, but is not limited to, a synthetic fiber screen, a stainless-steel screen, or a natural fiber screen.

In block 103, referring to FIGS. 3 to 5, the screen-printing plate 7 is placed above the first surface 11. A radiation layer 2 is printed on the first surface 11 through the hollow pattern 74 by a planar printing process. The radiation layer 2 includes a first radiation region 21, at least one second radiation region 22 electrically connected to the first radiation region 21, and a feed end 24 electrically connected to the first radiation layer 21. A region between the first radiation region 21 and each second radiation region 22 is defined as a pre-bending region 23.

The planar printing process can be carried out by applying a conductive paste on a surface of the hollow pattern 74 away from the first surface 11. The conductive paste passes through the holes of the hollow pattern 74 and gathers on the first surface 11. Then, the conductive paste is cured to form the radiation layer 2.

The radiation layer 2 is formed by the planar printing process through the screen-printing plate 7, which simplifies the manufacturing process. The planar printing process also saves materials, and is more environmentally friendly than a manufacturing process of a circuit board. Furthermore, a cost of the planar printing process is low and high-temperature processes are not required.

In the screen-printing plate 7, the connecting frame 72 and the silk screen 73 are heterogeneous materials. The hardness of the connecting frame 72 is less than that of the silk screen 73. The silk screen 73 is a stainless-steel screen. The connecting frame 72 is made of polymer, which is elastic and cheaper than the stainless-steel. The connecting frame 72 ensures that the silk screen 73 is closely attached to the first surface 11 of the base layer 1 during printing. Thus, precision and accuracy of the radiation layer 2 are improved, and a durability of the screen-printing plate 7 can be improved. In addition, the connecting frame 72 is used to replace a portion of the silk screen 73 to reduce the cost of the screen-printing plate 7.

In an embodiment, the conductive paste is made of silver, copper, or carbon.

In an embodiment, a thickness of the radiation layer 2 may be changed by printing multiple layers of the conductive paste according to actual needs.

In an embodiment, the conductive paste is cured by a sintering process.

In an embodiment, the curing temperature of the conductive paste is in a range of 70° C. to 250° C.

In an embodiment, the feed end 24 extends from the first radiation layer 21. An end of the feed end 24 away form the first radiation layer 21 goes beyond the second radiation layer 22.

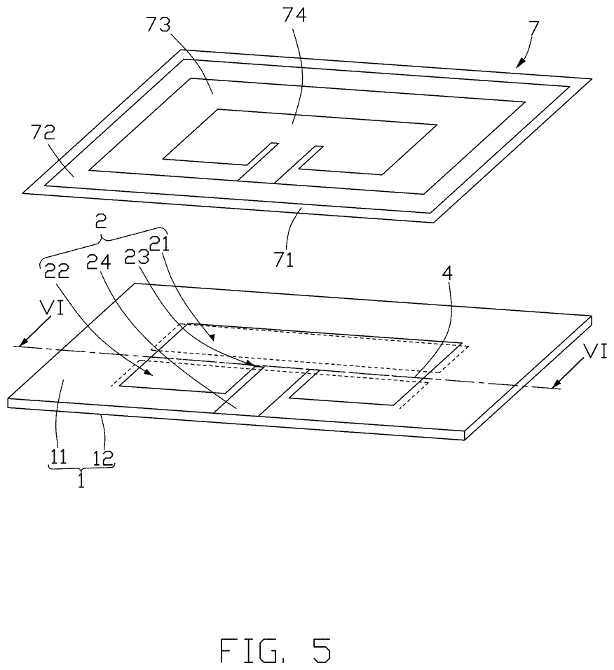

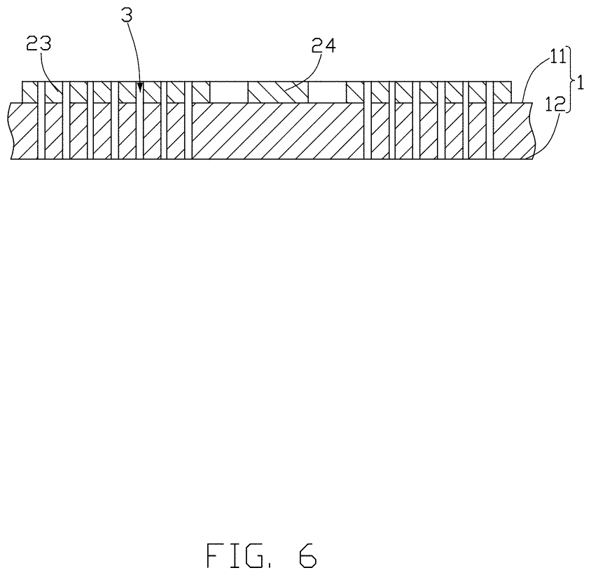

In block 104, referring to FIGS. 5 and 6, a plurality of through holes 3 are defined on the pre-bending region 23, and the through holes 3 cooperatively form a pre-bending line 4.

In an embodiment, the through holes 3 are formed by laser drilling.

In an embodiment, a portion of the base layer 1 without the cured conductive paste can be cut off before or after the through holes 3 are formed.

In an embodiment, each through hole 3 may be circular, rectangular, or other shape. In an embodiment, each through hole 3 is circular.

In an embodiment, a width of each through hole 3 ranges from 0.05 mm to 0.5 mm. If the width of the through hole 3 is too large, the strength of the pre-bending region 23 may be reduced. If the width is too small, the flexibility of the pre-bending region 23 may be reduced.

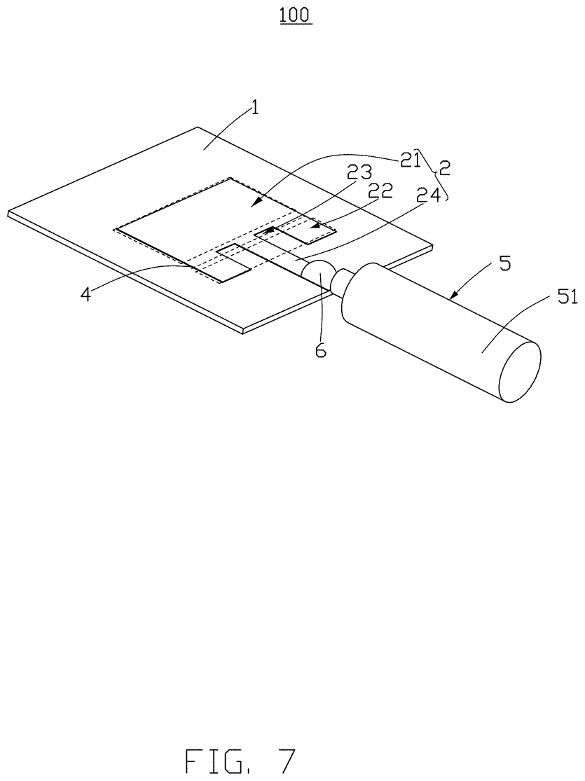

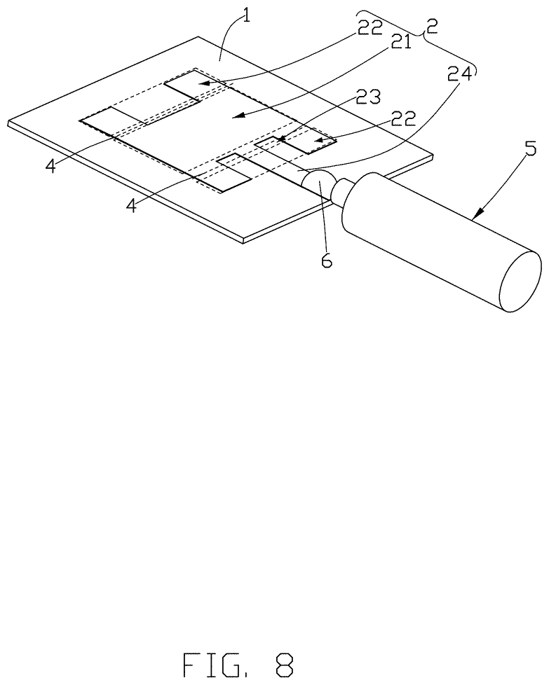

In block 105, referring to FIGS. 7 and 8, a feeder 5 is provided. The feeder 5 is fixed and electrically connected to the feed end 24 by a fixing portion 6, to obtain the planar printed antenna 100.

In an embodiment, the feeder 5 is a radio frequency (RF) feeder. One end of the feeder 5 is connected to the feed end 24 of the radiation layer 2, and the other end has an RF connector 51. The RF connector 51 is connected to the RF communication module (not shown) to transmit RF signals.

In an embodiment, the fixing portion 6 is made of conductive adhesive or solder paste. One end of the feeder 5 away from the RF connector 51 can be fixed on the feed end 24 by a conductive glue or a low-temperature solder. The feeder 5 is fixed on the radiation layer 2 by a low-temperature welding process, which is easily carried out, has low energy consumption, is conducive to reducing the cost, and will not affect the performance of feeder 5.

In an embodiment, after welding the feeder 5, edges of the radiation layer 2 can also be cut off to remove excess portions.

In an embodiment, referring to FIG. 7, the planar printed antenna 100 has two second radiation regions 22 disposed on opposites sides of the first radiation regions 21.

In another embodiment, referring to FIG. 8, the planar printed antenna 100 has four second radiation regions 22. The four second radiation regions 22 are divided into two groups. Each group has two second radiation regions 22. The two groups are disposed on opposites sides of the first radiation regions 21.

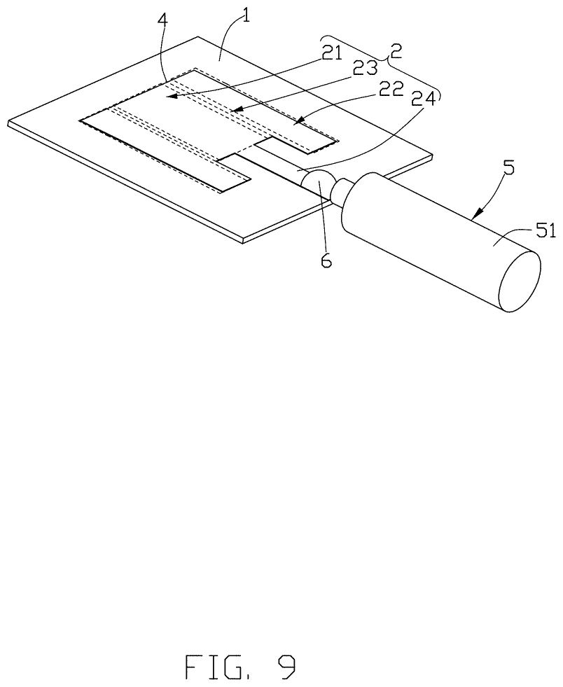

In another embodiment, referring to FIG. 9, the planar printed antenna 100 has two second radiation regions 22 disposed on opposites sides of the first radiation regions 21. A difference from the planar printed antenna 100 in FIG. 7 is that one pre-pending region 23 is defined between the first radiation region 21 and each second radiation region 22.

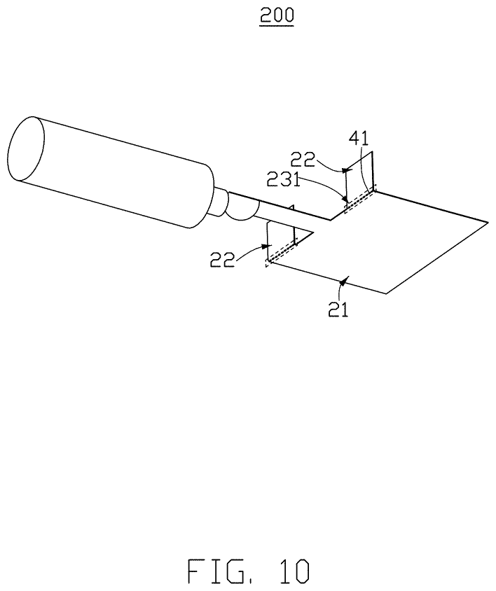

In block 106, referring to FIGS. 7 and 10, the second radiation region 21 is bent along the pre-bending line 4, to obtain a three-dimensional printed antenna 200. In the three-dimensional printed antenna 200, the pre-bending line 4 is bent to form a bent line 41, and the pre-bending region 23 is bent to form a bent region 231.

FIG. 7 illustrates an embodiment of a planar printed antenna 100. Referring to FIGS. 5, and 6, the planar printed antenna 100 includes a base layer 1, a radiation layer 2, a plurality of through holes 3, and a feeder 5. The base layer 1 includes a first surface 11 and a second surface 12 opposite to the first surface 11. The radiation layer 2 is disposed on the first surface 11. The radiation layer 2 includes a first radiation region 21, at least one second radiation region 22 electrically connected to the first radiation region 21, and a feed end 24 electrically connected to the first radiation layer 21. The feeder 5 is fixed on the feed end 24 by a fixing portion 6. A region between the first radiation region 21 and each second radiation region 22 is defined as a pre-bending region 23. The through holes 3 are defined on the pre-bending region 23, and the through holes 3 cooperatively form a pre-bending line 4. The first radiation region 21 is bent along the pre-bending line 4, causing the first radiation region 21 and the second radiation region 22 to be on different planes.

In an embodiment, a width of each through hole 3 ranges from 0.05 mm to 0.5 mm.

In an embodiment, the base layer 1 is made of an insulating resin, such as polyphenylene oxide (PPO), polyimide (PI), polyethylene terephthalate (PET), and polyethylene naphthalate (PEN).

In an embodiment, the feed end 24 extends from the first radiation layer 21. An end of the feed end 24 away from the first radiation layer 21 goes beyond the second radiation layer 22.

In an embodiment, the fixing portion 6 is made of conductive adhesive or solder paste.

In an embodiment, referring to FIG. 7, the planar printed antenna 100 has two second radiation regions 22. The two second radiation regions 22 are disposed on opposites sides of the first radiation regions 21.

In another embodiment, referring to FIG. 8, the planar printed antenna 100 has four second radiation regions 22. The four second radiation regions 22 are divided into two groups. Each group has two second radiation regions 22. The two groups are disposed on opposites sides of the first radiation regions 21.

In another embodiment, referring to FIG. 9, the planar printed antenna 100 has two second radiation regions 22 disposed on opposites sides of the first radiation regions 21. A difference from the planar printed antenna 100 in FIG. 7 is that one pre-pending region 23 is defined between the first radiation region 21 and each second radiation region 22.

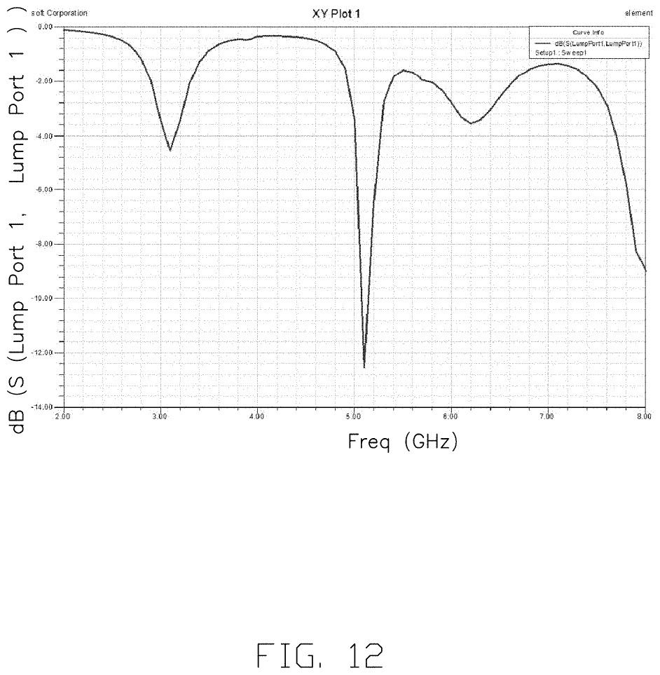

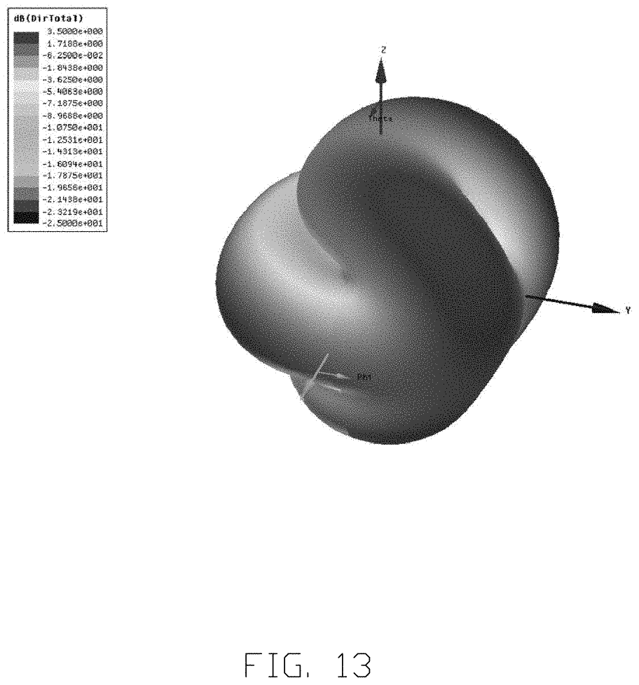

FIG. 12 illustrates a diagram showing gain test of the planar printed antenna 100. FIG. 13 illustrates a photo showing gain test of the planar printed antenna 100. The voltage standing wave ratio (VSWR) bandwidth obtained by using the planar printed antenna 100 is narrow. The gain and center frequency of the planar printed antenna 100 are good.

FIG. 10 illustrates an embodiment of a three-dimensional printed antenna 200. Each second radiation region 21 is bent along the pre-bending line 4 to obtain the three-dimensional printed antenna 200. In the three-dimensional printed antenna 200, the first radiation region 21 and the second radiation region 22 are on different planes, the pre-bending line 4 is bent to form a bent line 41, and the pre-bending region 23 is bent to form a bent region 231.

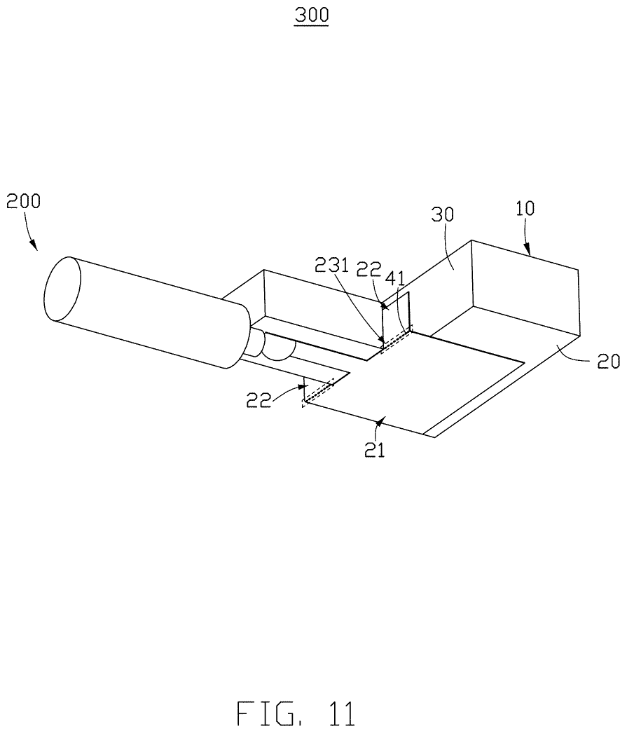

FIG. 11 illustrates an embodiment of an electronic device 300 which includes a main board 10 and the three-dimensional printed antenna 200.

In an embodiment, referring to FIGS. 10 and 11, during a bending event, there are two second radiation regions 22 around the first radiation region 21. The first radiation region 21 and the second radiation regions 22 can be on different surfaces of the main board 10. For example, the first radiation region 21 is formed on a third surface 20 of the main board 10, and the two second radiation regions 22 are formed on a fourth surface 30 and adjacent to the first radiation region 21. The three-dimensional printed antenna 200 can increase a radiation area, and does not occupy a large space of the main board 10, which can reduce a size of an electronic device 300 using the three-dimensional printed antenna 200.

In an embodiment, the first radiation region 21 and the second radiation region 22 can be bonded to the main board 10 by an adhesive (such as PET double-sided adhesive, PI double-sided adhesive, UV curing adhesive, or pressure-sensitive adhesive). The adhesive can be cured such as by thermal curing, pressure-sensitive curing, or UV curing.

With the above configuration, since the planar printed antenna 100 can be formed by printing the radiation layer 2 on the base layer 1, the manufacturing process of the planar printed antenna 100 is simpler and has high efficiency. Furthermore, the planar printing process has a short forming cycle, high efficiency, low cost, and low energy consumption. The planar printing process is environmentally friendly. Moreover, the shape and the size of the planar printed antenna 100 are not limited and can be made according to actual needs. The through holes 3 allow easy bending of the pre-bending region 23 to form the bent region 231, which will not affect signal transmission of the radiation layer 2 on the three-dimensional printed antenna 200. The through holes 3 also avoid separation of the radiation layer 2 from the base layer 1.

The planar printed antenna 100 is folded to form the three-dimensional printed antenna 200. The forming process of the three-dimensional printed antenna 200 is simple, the forming cycle is short, and the forming efficiency is high. The shape of the three-dimensional printed antenna 200 is not limited and the cost three-dimensional printed antenna 200 is low which is suitable for a disposable electronic device. The three-dimensional printed antenna 200 can increase a radiation area, and not occupy too much space of the main board 10, which is conducive to the lightness and shortness of an electronic device 300. The three-dimensional printed antenna 200 especially suitable for use in a disposable electronic device.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure, up to and including the full extent established by the broad general meaning of the terms used in the claims.

What is claimed is:

1. A method for manufacturing a three-dimensional printed antenna, comprising:
providing a base layer, the base layer comprising a first surface and a second surface opposite to the first surface;
providing a screen-printing plate, the screen-printing plate comprising a hollow outer frame, a hollow connecting frame connected to an inner wall of the outer frame, and a silk screen connected to an inner wall of the connecting frame, the silk screen defining a hollow pattern, a hardness of the connecting frame being less than a hardness of the silk screen;
disposing the screen-printing plate above the first surface, applying a conductive paste onto the screen-printing plate by a planar printing process, causing the conductive paste to pass through the hollow pattern to form a radiation layer on the first surface, the radiation layer comprising a first radiation region, at least one second radiation region electrically connected to the first radiation region, and a feed end electrically connected to the first radiation region, a region between the first radiation region and each of the at least one second radiation region being defined as a pre-bending region;
forming a plurality of through holes on the pre-bending region to form a pre-bending line;
electrically connecting a feeder to the feed end; and
bending the at least one second radiation region with respect to the first radiation region along the pre-bending line, to obtain the three-dimensional printed antenna.

2. The method of claim 1, further comprising:
curing the conductive paste on the first surface to form the radiation layer.

3. The method of claim 2, wherein the conductive paste is made of silver, copper, or carbon.

4. The method of claim 2, wherein the conductive paste is cured by a sintering process.

5. The method of claim 4, wherein a curing temperature of the conductive paste is in a range of 70° C. to 250° C.

6. The method of claim 1, wherein the connecting frame is made of polymer, and the silk screen is made of metal.

7. The method of claim 1, wherein a width of each of the plurality of through holes ranges from 0.05 mm to 0.5 mm.

8. The method of claim 1, wherein the plurality of through holes is formed by laser drilling.

9. The method of claim 1, wherein the feeder is connected to the feed end by a fixing portion, and the fixing portion is made of conductive adhesive or solder paste.

10. The method of claim 1, wherein the base layer is made of an insulating resin selected from a group consisting of polyphenylene oxide (PPO), polyimide (PI), polyethylene terephthalate (PET), and polyethylene naphthalate (PEN).

11. A three-dimensional printed antenna, comprising:
a base layer comprising a first surface and a second surface opposite to the first surface;
a radiation layer disposing on the first surface, the radiation layer comprising a first radiation region, at least one second radiation region electrically connected to the first radiation region, and a feed end electrically connected to the first radiation layer, a region between the first radiation region and each of the at least one second radiation region being defined as a bent region;
a plurality of through holes forming on the bent region, and a bent line being defined by the plurality of through holes, the at least one second radiation region being bent with respect to the first radiation region along the bent line; and
a feeder electrically connecting to the feed end.

12. The three-dimensional printed antenna of claim 11, wherein the radiation layer is made of silver, copper, or carbon.

13. The three-dimensional printed antenna of claim 11, wherein a width of each of the plurality of through holes ranges from 0.05 mm to 0.5 mm.

14. The three-dimensional printed antenna of claim 11, wherein the feeder is connected to the feed end by a fixing portion, and the fixing portion is made of conductive adhesive or solder paste.

15. The three-dimensional printed antenna of claim 11, wherein the base layer is made of an insulating resin selected from a group consisting of polyphenylene oxide (PPO), polyimide (PI), polyethylene terephthalate (PET), and polyethylene naphthalate (PEN).

16. The three-dimensional printed antenna of claim 11, wherein the radiation layer comprises two second radiation regions disposed on opposites sides of the first radiation region;
or, the radiation layer comprises four second radiation regions, the four second radiation regions are divided into two groups, each of the two groups has two of the four second radiation regions, the two groups disposed on opposites sides of the first radiation regions.

17. An electronic device, comprising:
a three-dimensional printed antenna, comprising:
a base layer comprising a first surface and a second surface opposite to the first surface;
a radiation layer disposing on the first surface, the radiation layer comprising a first radiation region, at least one second radiation region electrically connected to the first radiation region, and a feed end electrically connected to the first radiation layer, a region between the first radiation region and each of the at least one second radiation region being defined as a bent region;
a plurality of through holes forming on the bent region, and a bent line being defined by the plurality of through holes, the at least one second radiation region being bent with respect to the first radiation region along the bent line; and
a feeder fixing electrically connecting to the feed end; and
a main board comprising a third surface and at least one fourth surface connected to the third surface; wherein the first radiation region is formed on the third surface, the at least one second radiation region is formed on the at least one fourth surface.

18. The electronic device of claim 17, wherein the first radiation region and the at least one second radiation region is bonded on the main board by an adhesive.

19. The electronic device of claim 18, wherein the adhesive is cured by thermal, pressure, or UV.

20. The electronic device of claim 17, wherein the radiation layer comprises two second radiation regions disposed on opposites sides of the first radiation region;
or, the radiation layer comprises four second radiation regions, the four second radiation regions are divided into two groups, each of the two groups has two of the four second radiation regions, the two groups disposed on opposites sides of the first radiation regions.
